(19) United States
(12) Patent Application Publication
(10) Pub. No.: US 2020/0006705 A1
(43) Pub. Date: Jan. 2, 2020

(54) DISPLAY PANEL AND DISPLAY DEVICE

(71) Applicant: Wuhan China Star Optoelectronics Semiconductor Display Technology Co., Ltd., Wuhan (CN)

(72) Inventors: Xueyun LI, Wuhan (CN); Yuejun TANG, Wuhan (CN)

(73) Assignee: Wuhan China Star Optoelectronics Semiconductor Display Technology Co., Ltd., Wuhan (CN)

(21) Appl. No.: 16/095,361

(22) PCT Filed: Aug. 10, 2018
(86) PCT No.: PCT/CN2018/099776

§ 371 Date: Oct. 21, 2018

(30) Foreign Application Priority Data
Jul. 2, 2018 (CN) 201810706711.9

(51) Int. Cl. H01L 51/52; H01L 27/32; H01L 51/56

(52) U.S. Cl. CPC H01L 51/5256; H01L 2227/323; H01L 51/56; H01L 27/3258

(57) ABSTRACT

An organic light emitting diode (OLED) display panel and an encapsulation method thereof are provided. The OLED display panel comprises a substrate, a thin film transistor layer disposed on the substrate, an OLED luminescent layer and an encapsulation layer. The OLED luminescent layer comprises OLED luminescent devices, and the encapsulation layer includes inorganic layers and organic layers stacked alternately, wherein at least one inorganic layer contacts at least one inorganic material film of the OLED luminescent layer or the thin film transistor layer through a reserved area to form at least an enhanced encapsulation encirclement surrounding the OLED luminescent devices.

### FIELD OF INVENTION

The present disclosure relates to a technical field of display manufacturing, and in particular to an organic light emitting diode (OLED) display panel and an encapsulation method thereof.

### BACKGROUND OF INVENTION

Organic light emitting diode (OLED) display panels generally have a first electrode, a second electrode, and an organic light emitting material located in an intermediate layer between the first electrode and the second electrode. Organic light emitting displays feature wide viewing angles, high contrast, and fast response times. Recently, research has been conducted on manufacturing slimmer display devices. Encapsulation is required in manufacturing OLED displays, and encapsulation functions to block outside vapor/oxygen from entering the OLED display and affect its display life. Currently, cover encapsulation and film encapsulation are used on the market. However, in certain environments, such as high temperature, high humidity, or in a surface state, vapor/oxygen still penetrates the inside of devices. As the requirements for OLED display devices become higher and higher, improving the performance of avoidance of vapor/oxygen and increasing service life have become the focus of attention.

As a result, it is necessary to provide an organic light emitting diode (OLED) display panel and an encapsulation method thereof to solve the problems existing in conventional technologies, as described above.

### SUMMARY OF INVENTION

An object of the present disclosure is to provide an organic light emitting diode (OLED) display panel and an encapsulation method thereof, which can enhance the encapsulation performance of OLED display panel and improve an effect that vapor/oxygen is blocked from entering the OLED display panel. Thus, the OLED display panel life can be improved.

To solve the above problems, the present disclosure provides the following technical solutions:

A display panel of the present disclosure is provided, which comprises a substrate, a thin film transistor layer, an organic light emitting diode (OLED) luminescent layer and an encapsulation layer. The thin film transistor layer is disposed on the substrate. The OLED luminescent layer is disposed on the thin film transistor layer and including OLED luminescent devices. The encapsulation layer is disposed on the OLED luminescent layer, wherein the encapsulation layer is an encapsulation cover or a thin film encapsulation layer and includes inorganic layers and organic layers stacked alternately. At least one inorganic layer of the encapsulation layer contacts at least one inorganic material film of the OLED luminescent layer or the thin film transistor layer through a reserved area to form an enhanced encapsulation encirclement surrounding the OLED luminescent devices for encapsulating the OLED display panel.

In one embodiment of the present disclosure, the OLED luminescent layer includes at least a first inorganic material film, the reserved area is disposed on a non-display area located at a periphery of the OLED luminescent layer, and the first inorganic material film is exposed from the reserved area.

In one embodiment of the present disclosure, the OLED luminescent devices are disposed on a side of the first inorganic material film far away from the substrate, and at least one inorganic layer of the encapsulation layer contacts the first inorganic material film through the reserved area to form the enhanced encapsulation encirclement.

In one embodiment of the present disclosure, the thin film transistor layer includes at least a second inorganic material film, the reserved area is disposed on a preset position of a periphery of the thin film transistor layer, and the second inorganic material film is exposed from the reserved area.

In one embodiment of the present disclosure, the OLED luminescent devices correspond to a non-reserved area within the reserved area, and at least one inorganic layer of the encapsulation layer contacts the second inorganic material film through the reserved area.

In one embodiment of the present disclosure, the thin film transistor layer includes thin film transistors, and the thin film transistors are disposed on a side of the second inorganic material film far away from the substrate to form the enhanced encapsulation encirclement surrounding the OLED luminescent devices and the thin film transistors.

In one embodiment of the present disclosure, the substrate includes a third inorganic material film, the thin film transistor layer includes thin film transistors, and the third inorganic material film contacts the second inorganic material film at a preset position of the periphery of the substrate to form the enhanced encapsulation encirclement surrounding the OLED luminescent devices and the thin film transistors.

In one embodiment of the present disclosure, the substrate includes a third inorganic material film, the reserved area is disposed on a preset position of a non-display area corresponding to a periphery of each of the thin film transistor layer and the OLED luminescent layer, the third inorganic material film is exposed from the reserved area, and at least one inorganic layer of the encapsulation layer contacts the third inorganic material film through the reserved area.

The present disclosure further provides an encapsulation method of an organic light emitting diode (OLED) display panel, the method comprises step S1, step S2 and step S3. Step S1 is providing a substrate and stacking a thin film transistor layer and an OLED luminescent layer on the substrate successively to form an OLED display panel to be encapsulated, wherein an inorganic material film of the thin film transistor layer or the OLED luminescent layer is exposed from a preset area of a non-display area located at a periphery of the substrate. Step S2 is processing an encapsulation process, wherein an inorganic layer is disposed on the OLED display panel, and the inorganic layer contacts the inorganic material film of the thin film transistor layer or the OLED luminescent layer through the preset area to form an enhanced encapsulation encirclement surrounding OLED luminescent devices of the OLED luminescent layer. Step S3 is encapsulating an encapsulation cover on the inorganic layer or forming a thin film encapsulation layer including inorganic layers and organic layers stacked alternately.

The present disclosure further provides an organic light emitting diode (OLED) display panel, which comprises a substrate, a thin film transistor layer and an encapsulation layer. The thin film transistor layer is disposed on the substrate. The OLED luminescent layer is disposed on the thin film transistor layer and including OLED luminescent devices. The encapsulation layer is disposed on the OLED luminescent layer, wherein the encapsulation layer includes inorganic layers and organic layers stacked alternately. At least one inorganic layer of the encapsulation layer contacts at least one inorganic material film of the OLED luminescent layer or the thin film transistor layer through a reserved area to form an enhanced encapsulation encirclement surrounding the OLED luminescent devices for encapsulating the OLED display panel.

In one embodiment of the present disclosure, the OLED luminescent layer includes at least a first inorganic material film, the reserved area is disposed on a non-display area located at a periphery of the OLED luminescent layer, and the first inorganic material film is exposed from the reserved area.

In one embodiment of the present disclosure, the OLED luminescent devices are disposed on a side of the first inorganic material film far away from the substrate, and at least one inorganic layer of the encapsulation layer contacts the first inorganic material film through the reserved area to form the enhanced encapsulation encirclement.

In one embodiment of the present disclosure, the thin film transistor layer includes at least a second inorganic material film, the reserved area is disposed on a preset position located at a periphery of the thin film transistor layer, and the second inorganic material film is exposed from the reserved area.

In one embodiment of the present disclosure, the OLED luminescent devices correspond to a non-reserved area within the reserved area, and at least one inorganic layer of the encapsulation layer contacts the second inorganic material film through the reserved area.

In one embodiment of the present disclosure, the thin film transistor layer includes thin film transistors, and the thin film transistors are disposed on a side of the second inorganic material film far away from the substrate to form the enhanced encapsulation encirclement surrounding the OLED luminescent devices and the thin film transistors.

In one embodiment of the present disclosure, the substrate includes a third inorganic material film, the thin film transistor layer includes thin film transistors, and the third inorganic material film contacts the second inorganic material film at a preset position of the periphery of the substrate to form the enhanced encapsulation encirclement surrounding the OLED luminescent devices and the thin film transistors.

In one embodiment of the present disclosure, the substrate includes a third inorganic material film, the reserved area is disposed on a preset position of a non-display area corresponding to a periphery of each of the thin film transistor layer and the OLED luminescent layer, the third inorganic material film is exposed from the reserved area, and at least one inorganic layer of the encapsulation layer contacts the third inorganic material film through the reserved area.

The beneficial effect is that the OLED display panel and an encapsulation method thereof are provided. The enhanced encapsulation encirclement formed with inorganic material is formed through the inorganic layers of the encapsulation layer and the thin film transistor layer for encapsulating the OLED display panel, or is formed through the inorganic layer of the encapsulation layer, the thin film transistor layer and the substrate for encapsulating the OLED display panel. The enhanced encapsulation encirclement formed with inorganic material is embedded in the inner of the thin film transistor layer or the substrate. The display panel border width does not be increased, and it is not to be damaged to increase its stability. The inner is hart to contact vapor/oxygen, and it is easier to achieve to enhance the encapsulation performance of OLED display panel. At the same time, other structures of inorganic layer in the process can be used to reduce the cost. Therefore, the present disclosure can improve an effect that vapor/oxygen is blocked from entering the OLED display panel. Thus, the OLED display panel life can be improved.

### DESCRIPTION OF DRAWINGS

In order to more clearly illustrate the embodiments or the prior art technical solutions embodiment of the present disclosure, will implement the following figures for the cases described in the prior art or require the use of a simple introduction. Obviously, the following description of the drawings are only some of those of ordinary skill in terms of creative effort without precondition, you can also obtain other drawings based on these drawings embodiments of the present disclosure.

FIG. 1 is a structural top view of an organic light emitting diode (OLED) display panel according an embodiment of the present disclosure.

FIG. 2 is a schematic diagram of a periphery of an organic light emitting diode (OLED) display panel according a first embodiment of the present disclosure.

FIG. 3A is a schematic diagram of a periphery of an organic light emitting diode (OLED) display panel according a second embodiment of the present disclosure.

FIG. 3B is a schematic diagram of another periphery of the OLED display panel according the second embodiment of the present disclosure.

FIG. 3C is a schematic diagram of another periphery of the OLED display panel according the second embodiment of the present disclosure.

FIG. 4A is a schematic diagram of a periphery of an organic light emitting diode (OLED) display panel according a third embodiment of the present disclosure.

FIG. 4B is a schematic diagram of another periphery of the OLED display panel according the third embodiment of the present disclosure.

FIG. 5 is a schematic diagram of a periphery of an organic light emitting diode (OLED) display panel according a fourth embodiment of the present disclosure.

FIG. 6 is a schematic diagram of another periphery of the OLED display panel according the fourth embodiment of the present disclosure.

FIG. 7 is a flow chart of an encapsulation method of an organic light emitting diode (OLED) display panel according an embodiment of the present disclosure.

### DETAILED DESCRIPTION OF PREFERRED EMBODIMENTS

Structure and technical means adopted by the present disclosure to achieve the above and other objects can be best understood by referring to the following detailed description of the preferred embodiments and the accompanying drawings. Furthermore, directional terms described by the present disclosure, such as upper, lower, front, back, left, right, inner, outer, side, longitudinal/vertical, transverse/horizontal, etc., are only directions by referring to the accompanying drawings, and thus the used directional terms are used to describe and understand the present disclosure, but the present disclosure is not limited thereto.

For the technical problems of an organic light emitting diode (OLED) display panel of the prior art, encapsulating performance of the encapsulation layer is poor, so that external vapor or oxygen enters the interior of the OLED display panel to affect the life of OLED display panel. Embodiments of the present disclosure can solve these defects.

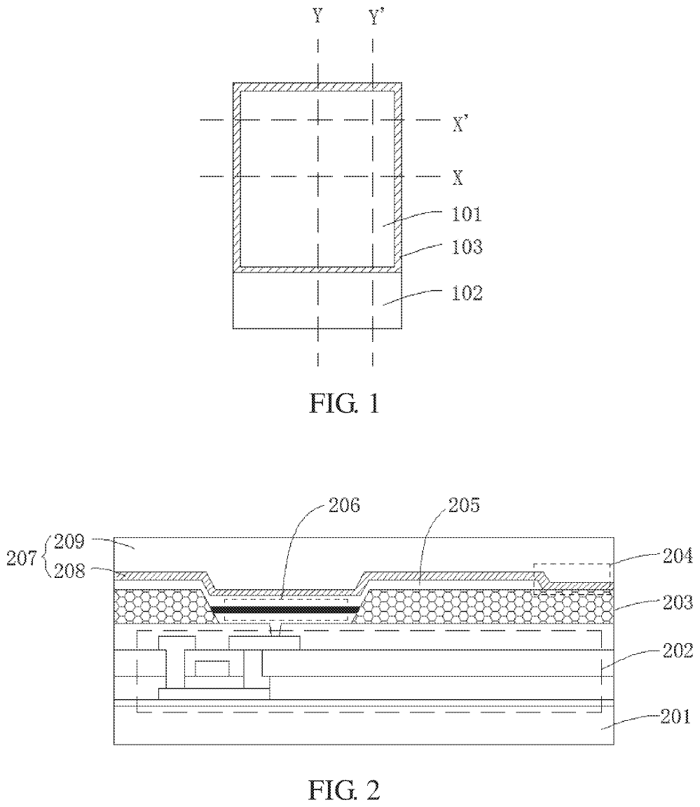

Referring to FIG. 1, a structural top view of an organic light emitting diode (OLED) display panel according an embodiment of the present disclosure is illustrated. The OLED display panel comprises a display area 101, a welding plate area 102, and an encapsulation periphery/frame area 103. The following embodiments in FIGS. 2-7 show sectional views along dotted line X or dotted line Y. The OLED display panel further shows a plurality of X/Y sections, and X′/Y′ sections is adopted an encapsulation method of the prior art. For example, the X′/Y′ sections are organic layers of an encapsulation layer contacted inorganic layers of a thin film transistor layer or a substrate. In the embodiments of the present disclosure, and the X′/Y′ sections cannot be available or partially available. The X′/Y′ sections are only an example, and not as a limitation.

Referring to FIG. 2, a schematic diagram of a periphery of an organic light emitting diode (OLED) display panel according a first embodiment of the present disclosure is illustrated. The OLED display panel comprises a substrate 201, a thin film transistor layer 202, an OLED luminescent layer, and an encapsulation layer 207. The thin film transistor layer 202 is disposed on the substrate 201, the OLED luminescent layer is disposed on the thin film transistor layer 202 and includes a pixel defining layer 203 and OLED luminescent devices 206, the pixel defining layer 203 is defined pixel areas, and the OLED luminescent devices 206 are located in the pixel areas, the encapsulation layer 207 is disposed on the OLED luminescent layer, and the encapsulation layer 207 includes inorganic layers and organic layers stacked alternately. The OLED luminescent layer includes a first inorganic material film, and the OLED luminescent devices 206 are disposed on a side of the first inorganic material film far away from the substrate 201. The first inorganic material film can be the pixel defining layer 203 but not be limited. A reserved area 204 is disposed on a non-display area located at a periphery of the OLED luminescent layer, and the first inorganic material film is exposed from the reserved area 204. Namely, when preparing the OLED luminescent devices 206 a cathode layer 205 is typically prepared over an entire surface. In the embodiment. The cathode layer 205 correspond to a non-reserved area within the reserved area 204 is prepared on a surface of the pixel defining layer 203, and the cathode layer 205 does not cover the reserved area 204. Therefore, first inorganic layers 208 of the encapsulation layer 207 contacts the pixel defining layer 203 through the reserved area 204 to form an enhanced encapsulation encirclement surrounding the OLED luminescent devices 206 for encapsulating the OLED display panel.

In addition, the thin film transistor layer 202 shown in the FIG. 2 adopts structure of top-gate type LTPS TFTs as an example but it is not limited. The first inorganic layers 208 are been as first encapsulation portions of the encapsulation layer 207, and second encapsulation portions 209 stacked alternately with inorganic layers and organic layers are disposed on the surface of the first inorganic layers 208. The other inorganic layers located at the encapsulation layer 207 also contact the first inorganic layers through the reserved area 204. In the embodiment, the reserved area 204 contact the first inorganic layers 208 through the pixel defining layer 203 being as a contacting layer. In the other embodiment, at least one of the metal layer (such as anode/cathode/auxiliary electrodes) and non-metallic inorganic material in the OLED luminescent layer can been as a contacting layer, and not limited here.

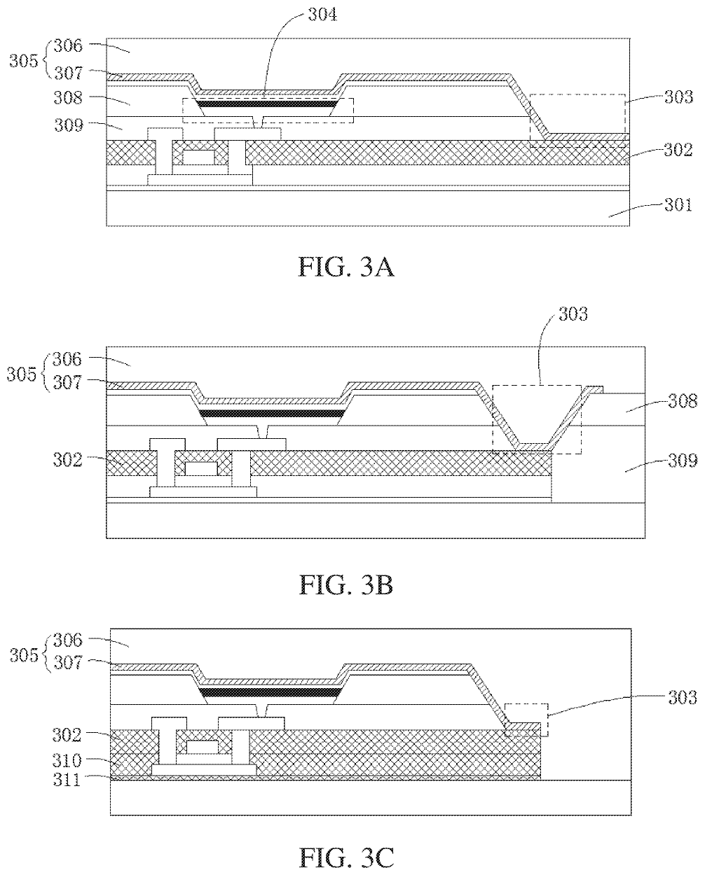

Referring to FIG. 3A, a schematic diagram of a periphery of an OLED display panel according a second embodiment of the present disclosure is illustrated. The OLED display panel comprises a substrate 301, a thin film transistor layer, a flat layer 309, a pixel defining layer 308, and OLED luminescent devices 304, wherein the thin film transistor layer is disposed on the substrate 301 and comprises a buffer layer, a gate insulating layer, an inter-insulation layer 302, thin film transistors, and an encapsulation layer 305. The buffer layer, the gate insulating layer and the inter-insulation layer are stacked successively on the substrate 301, and the thin film transistors pass through the gate insulating layer and the inter-insulation layer 302. The flat layer 309 is disposed on the thin film transistor layer. The pixel defining layer 308 is disposed on the flat layer 309, and the pixel defining layer 308 is defined pixel areas. The OLED luminescent devices 304 are disposed on the surface of the pixel defining layer 308 and correspond to the pixel areas. The encapsulation layer 305 is disposed on the surface of the OLED luminescent devices 304 for encapsulating the OLED display panel. The thin film transistor layer comprises a second inorganic material film includes but not limited to the inter-insulation layer 302. A reserved area 303 is disposed on a periphery of the thin film transistor layer, and the flat layer 309, the pixel defining layer 308 and the OLED luminescent devices 304 are disposed on a non-reserved area within the reserved area 303. The second inorganic material film is exposed from the reserved area 303. Namely, the second inorganic material film is exposed from the reserved area 303 corresponding the inter-insulation layer 302. An inner surface of the encapsulation layer 305 closing to a side of the OLED luminescent devices 304 can be first inorganic layers 307 as a first encapsulation portion. The first inorganic layers 307 contact the inter-insulation layer 302 through the reserved area 303 to form an enhanced encapsulation encirclement surrounding the OLED luminescent devices 304. A second encapsulation portion 306 is disposed on the surface of the first inorganic layers 307 of the encapsulation layer 305. In the embodiment, the flat layer 309, the pixel defining layer 308 are made of organic materials, such as polymethylmethacrylate (PMMA).

Referring to FIG. 3B, a schematic diagram of another periphery of the OLED display panel according the second embodiment of the present disclosure is illustrated. The difference compared to FIG. 3A is that an outside of the reserved area 303 for contacting the inter-insulation layer 302 in the first inorganic layers 307 further has the flat layer 309, the pixel defining layer 308, and the second encapsulation portion 306 of the encapsulation layer 305. The encapsulation layer 305 can be an encapsulation cover or the other layer of the thin film transistor layer.

Referring to FIG. 3C, a schematic diagram of another periphery of the OLED display panel according the second embodiment of the present disclosure is illustrated. The difference compared to FIG. 3A is that an outside of the reserved area 303 for contacting the inter-insulation layer 302 in the first inorganic layers 307 is the second encapsulation portion 306 of the encapsulation layer 305. The buffer layer 311, the gate insulating layer 310, and the inter-insulation layer 302 of the thin film transistor layer are made of inorganic materials, such as SiNx or SiOx.

In the second embodiment, a first layer located at an inner surface of the encapsulation layer 305 is an inorganic layer. In the thin film transistor layer including films and structure, the reserved area 303 is reserved to contact the first inorganic layers 307 of the encapsulation layer 305. When forming the organic material film such as flat layer 309 or pixel defining layer 308, the reserved area 303 is formed spaces or holes. In the encapsulating operation, the first inorganic layers 307 of the encapsulation layer 305 contact the second inorganic material film of the thin film transistor layer at the reserved area 303 to form an enhanced encapsulation encirclement with inorganic materials.

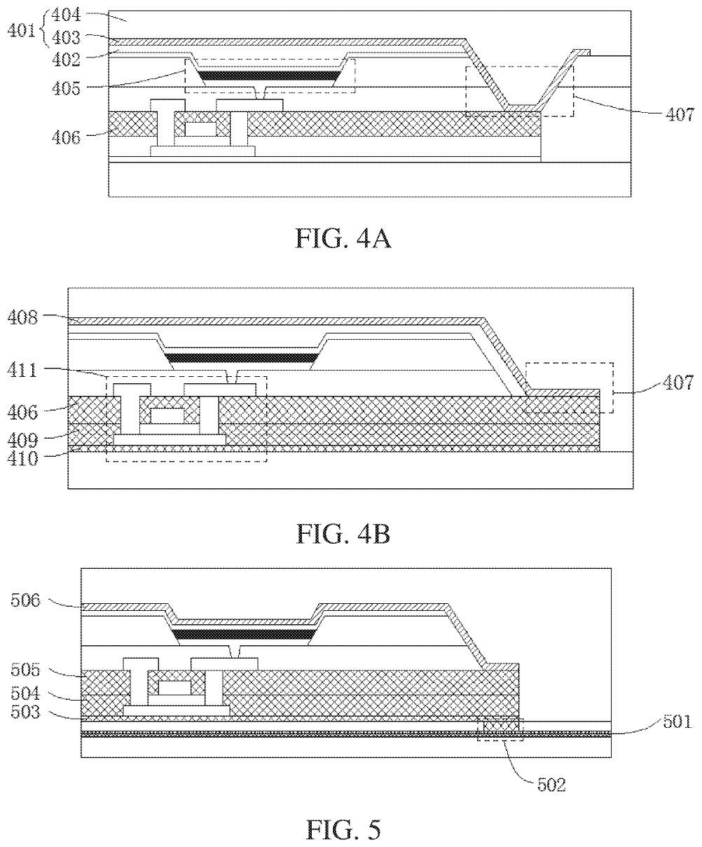

Referring to FIG. 4A, a schematic diagram of a periphery of an organic light emitting diode (OLED) display panel according a third embodiment of the present disclosure is illustrated. The embodiment is similar to said second embodiment in FIG. 3B, and the difference compared to FIG. 3B is that an encapsulation layer 401 is a thin film encapsulation layer. The encapsulation layer 401 comprises a first organic layer 402, a first inorganic layer 403, and another encapsulation films 404. The first organic layer 402 is reserved with a reserved area 407, and the first inorganic layer 403 contacts an inter-insulation layer 406 with inorganic material in the thin film transistor layer through the reserved area 407. An enhanced encapsulation encirclement is formed between the first inorganic layer 403 and the inter-insulation layer 406 to surround OLED luminescent devices 405.

Referring to FIG. 4B, a schematic diagram of another periphery of the OLED display panel according the third embodiment of the present disclosure is illustrated. The embodiment is similar to said second embodiment in FIG. 3C, and the difference compared to FIG. 3C is that an inorganic layer 408 located at a middle portion of the encapsulation layer contact an inter-insulation layer 406, a gate insulating layer 409 and buffer layer 410 of the thin film transistor layer at the reserved area 407. An enhanced encapsulation encirclement with inorganic materials is formed to surround thin film transistors 411 and OLED luminescent devices 405.

Referring to FIG. 5, a schematic diagram of a periphery of an organic light emitting diode (OLED) display panel according a fourth embodiment of the present disclosure is illustrated. The difference compared to the second embodiment in FIG. 3C is that the substrate of the OLED display panel is a flexible substrate or a film substrate. The substrate is a multi-layer structure with inorganic/organic material. The figure shows the substrate including a third inorganic material film 501, a reserved area 502 is disposed on a preset position of a periphery of the substrate. The third inorganic material film 501 is exposed from the reserved area 502 by digging holes. The third inorganic material film 501 contacts the second inorganic material film of the thin film transistor layer disposed on the surface of the substrate at the reserved area 502, wherein the second inorganic material film comprises a buffer layer 503, a gate insulating layer 504, and an inter-insulation layer 505. Thereby, an enhanced encapsulation encirclement is formed to surround OLED luminescent devices and thin film transistors.

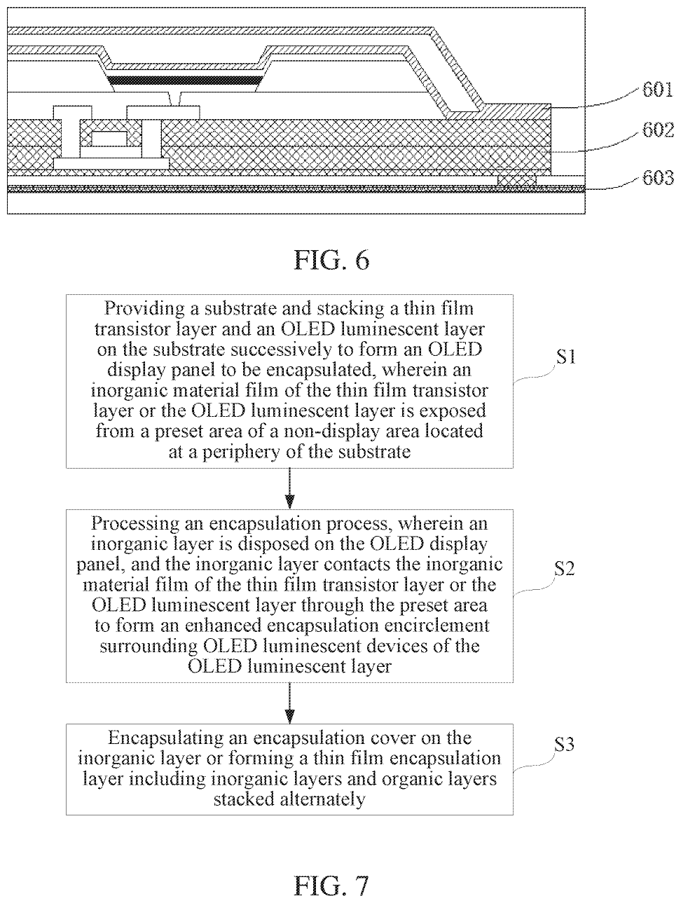

In addition, the OLED display panel of the embodiment further adopts the two structure of the second embodiment. An enhanced encapsulation encirclement is formed by the inorganic material of the encapsulation layer, the thin film transistor layer and the substrate, wherein an inorganic layer of the encapsulation layer can be a first layer, a middle layer, and an inorganic layer far away a side of the substrate. Possibly, the enhanced encapsulation encirclement comprises at least two inorganic layers of the encapsulation layer. Referring to FIG. 6, two inorganic layers 601 of the encapsulation layer, a second inorganic material film 602 of the thin film transistor layer and a third inorganic material film 603 of the substrate are formed an enhanced encapsulation encirclement surrounding OLED luminescent devices and thin film transistors through a reserved area.

The reserved areas in the schematic diagrams of the present disclosure are disposed on the buffer layer, the gate insulating layer, and the inter-insulation layer of the thin film transistor layer as contacting layers, but the contacting layers are not limited thereto. For example, the second inorganic material film of the reserved area further can be one of the metal layers of the scan line/data line of the thin film transistor layer. The first/second inorganic material film contacted the reserved area further can be one of the metal layers of the scan line/data line/anode/cathode, and be a contacting layer with the buffer layer, the gate insulating layer, and the inter-insulation layer. The schematic diagrams of the embodiment of the invention disclosure are not shown.

Referring to FIG. 5, the present disclosure further provides an encapsulation method of an organic light emitting diode (OLED) display panel, the method comprises step S1, step S2 and step S3 in following:

In step S1, it is providing a substrate and stacking a thin film transistor layer and an OLED luminescent layer on the substrate successively to form an OLED display panel to be encapsulated, wherein an inorganic material film of the thin film transistor layer or the OLED luminescent layer is exposed from a preset area of a non-display area located at a periphery of the substrate.

In step S2, it is processing an encapsulation process, wherein an inorganic layer is disposed on the OLED display panel, and the inorganic layer contacts the inorganic material film of the thin film transistor layer or the OLED luminescent layer through the preset area to form an enhanced encapsulation encirclement surrounding OLED luminescent devices of the OLED luminescent layer.

In step S3, it is encapsulating an encapsulation cover on the inorganic layer or forming a thin film encapsulation layer including inorganic layers and organic layers stacked alternately.

The OLED display panel of the present disclosure has four structures including a substrate, a thin film transistor layer, an OLED luminescent layer and an encapsulation layer. The substrate can be any suitable insulating material, such as glass, polyimide (PI), polycarbonate (PC), polyethersulfone (PES), polyethylene terephthalate (PET), etc. The thin film transistor layer includes thin film transistor arrays for controlling the OLED luminescent layer, circuit signal lines, and traces. The OLED luminescent layer includes anode, luminescent material layer and cathode. The encapsulation layer is an encapsulation cover or a thin film encapsulation layer. The thin film encapsulation layer can be an encapsulation film of a multilayer thin film structure obtained by sequentially depositing inorganic materials and coating organic materials. The inorganic materials can protect OLED devices from moisture, foreign matter or contaminants. The organic material can help perform planarization and defect filling. The organic materials can include but not limited to conventional polymer (PMMA, PS), phenol-based polymeric derivative, propylene-based polymer, imine-based polymer, aryl ether-based polymer, amide-based polymer, fluorine-based polymer, p-xylylene polymer, etc. The inorganic materials can include but not limited to SiO2, SiNx, SiON, Al2O3, TiO2, Ta2O5, HfO2, ZrO2, etc. At the same time, the order in which the inorganic material and the organic material are formed is variable. Alternatively, the encapsulation layer can have a multilayer structure including at least one inorganic layer and at least one organic layer. The OLED display panel further comprises a layer or a structure including the substrate/thin film transistor layer/OLED luminescent layer/encapsulation layer, but it is not described above. The OLED display panel further comprises a layer or a structure that is not included in the substrate/thin film transistor layer/OLED luminescent layer/encapsulation layer, such as circular polarizer that resists ambient light reflection, etc.

The present disclosure provides the OLED display panel and an encapsulation method thereof. The enhanced encapsulation encirclement formed with inorganic material is formed through the inorganic layers of the encapsulation layer and the thin film transistor layer for encapsulating the OLED display panel, or is formed through the inorganic layer of the encapsulation layer, the thin film transistor layer and the substrate for encapsulating the OLED display panel. The enhanced encapsulation encirclement formed with inorganic material is embedded in the inner of the thin film transistor layer or the substrate. The display panel border width does not be increased, and it is not to be damaged to increase its stability. The inner is hart to contact vapor/oxygen, and it is easier to achieve to enhance the encapsulation performance of OLED display panel. At the same time, other structures of inorganic layer in the process can be used to reduce the cost. Therefore, the present disclosure can improve an effect that vapor/oxygen is blocked from entering the OLED display panel. Thus, the OLED display panel life can be improved.

The present disclosure has been described with preferred embodiments thereof and it is understood that many changes and modifications to the described embodiments can be carried out without departing from the scope and the spirit of the invention that is intended to be limited only by the appended claims.

What is claimed is:

1. An organic light emitting diode (OLED) display panel, comprising:
a substrate;
a thin film transistor layer disposed on the substrate;
an OLED luminescent layer disposed on the thin film transistor layer and including OLED luminescent devices; and
an encapsulation layer disposed on the OLED luminescent layer, wherein the encapsulation layer is an encapsulation cover or a thin film encapsulation layer and includes inorganic layers and organic layers stacked alternately;
wherein at least one inorganic layer of the encapsulation layer contacts at least one inorganic material film of the OLED luminescent layer or the thin film transistor layer through a reserved area to form an enhanced encapsulation encirclement surrounding the OLED luminescent devices for encapsulating the OLED display panel.

2. The organic light emitting diode (OLED) display panel according to claim 1, wherein the OLED luminescent layer includes at least a first inorganic material film, the reserved area is disposed on a non-display area located at a periphery of the OLED luminescent layer, and the first inorganic material film is exposed from the reserved area.

3. The organic light emitting diode (OLED) display panel according to claim 2, wherein the OLED luminescent devices are disposed on a side of the first inorganic material film far away from the substrate, and at least one inorganic layer of the encapsulation layer contacts the first inorganic material film through the reserved area to form the enhanced encapsulation encirclement.

4. The organic light emitting diode (OLED) display panel according to claim 1, wherein the thin film transistor layer includes at least a second inorganic material film, the reserved area is disposed on a preset position of a periphery of the thin film transistor layer, and the second inorganic material film is exposed from the reserved area.

5. The organic light emitting diode (OLED) display panel according to claim 4, the OLED luminescent devices correspond to a non-reserved area within the reserved area, and at least one inorganic layer of the encapsulation layer contacts the second inorganic material film through the reserved area.

6. The organic light emitting diode (OLED) display panel according to claim 5, wherein the thin film transistor layer includes thin film transistors, and the thin film transistors are disposed on a side of the second inorganic material film far away from the substrate to form the enhanced encapsulation encirclement surrounding the OLED luminescent devices and the thin film transistors.

7. The organic light emitting diode (OLED) display panel according to claim 5, wherein the substrate includes a third inorganic material film, the thin film transistor layer includes thin film transistors, and the third inorganic material film contacts the second inorganic material film at a preset position of the periphery of the substrate to form the enhanced encapsulation encirclement surrounding the OLED luminescent devices and the thin film transistors.

8. The organic light emitting diode (OLED) display panel according to claim 1, wherein the substrate includes a third inorganic material film, the reserved area is disposed on a preset position of a non-display area corresponding to a periphery of each of the thin film transistor layer and the OLED luminescent layer, the third inorganic material film is exposed from the reserved area, and at least one inorganic layer of the encapsulation layer contacts the third inorganic material film through the reserved area.

9. An encapsulation method of an organic light emitting diode (OLED) display panel, comprising steps of:
step S1: providing a substrate and stacking a thin film transistor layer and an OLED luminescent layer on the substrate successively to form an OLED display panel to be encapsulated, wherein an inorganic material film of the thin film transistor layer or the OLED luminescent layer is exposed from a preset area of a non-display area located at a periphery of the substrate;
step S2: processing an encapsulation process, wherein an inorganic layer is disposed on the OLED display panel, and the inorganic layer contacts the inorganic material film of the thin film transistor layer or the OLED luminescent layer through the preset area to form an enhanced encapsulation encirclement surrounding OLED luminescent devices of the OLED luminescent layer; and
step S3: encapsulating an encapsulation cover on the inorganic layer or forming a thin film encapsulation layer including inorganic layers and organic layers stacked alternately.

10. An organic light emitting diode (OLED) display panel, comprising:
a substrate;
a thin film transistor layer disposed on the substrate;
an OLED luminescent layer disposed on the thin film transistor layer and including OLED luminescent devices; and
an encapsulation layer disposed on the OLED luminescent layer, wherein the encapsulation layer includes inorganic layers and organic layers stacked alternately;
wherein at least one inorganic layer of the encapsulation layer contacts at least one inorganic material film of the OLED luminescent layer or the thin film transistor layer through a reserved area to form an enhanced encapsulation encirclement surrounding the OLED luminescent devices for encapsulating the OLED display panel.

11. The organic light emitting diode (OLED) display panel according to claim 10, wherein the OLED luminescent layer includes at least a first inorganic material film, the reserved area is disposed on a non-display area located at a periphery of the OLED luminescent layer, and the first inorganic material film is exposed from the reserved area.

12. The organic light emitting diode (OLED) display panel according to claim 11, wherein the OLED luminescent devices are disposed on a side of the first inorganic material film far away from the substrate, and at least one inorganic layer of the encapsulation layer contacts the first inorganic material film through the reserved area to form the enhanced encapsulation encirclement.

13. The organic light emitting diode (OLED) display panel according to claim 10, wherein the thin film transistor layer includes at least a second inorganic material film, the reserved area is disposed on a preset position located at a periphery of the thin film transistor layer, and the second inorganic material film is exposed from the reserved area.

14. The organic light emitting diode (OLED) display panel according to claim 13, wherein the OLED luminescent devices correspond to a non-reserved area within the reserved area, and at least one inorganic layer of the encapsulation layer contacts the second inorganic material film through the reserved area.

15. The organic light emitting diode (OLED) display panel according to claim 14, wherein the thin film transistor layer includes thin film transistors, and the thin film transistors are disposed on a side of the second inorganic material film far away from the substrate to form the enhanced encapsulation encirclement surrounding the OLED luminescent devices and the thin film transistors.

16. The organic light emitting diode (OLED) display panel according to claim 14, wherein the substrate includes a third inorganic material film, the thin film transistor layer includes thin film transistors, and the third inorganic material film contacts the second inorganic material film at a preset position of the periphery of the substrate to form the enhanced encapsulation encirclement surrounding the OLED luminescent devices and the thin film transistors.

17. The organic light emitting diode (OLED) display panel according to claim 10, wherein the substrate includes a third inorganic material film, the reserved area is disposed on a preset position of a non-display area corresponding to a periphery of each of the thin film transistor layer and the OLED luminescent layer, the third inorganic material film is exposed from the reserved area, and at least one inorganic layer of the encapsulation layer contacts the third inorganic material film through the reserved area.
